(19) United States
(12) Patent Application Publication
(10) Pub. No.: US 2013/0069172 A1
(43) Pub. Date: Mar. 21, 2013

(54) SEMICONDUCTOR DEVICE AND METHOD FOR FABRICATING THE SAME

(71) Applicants: CHIN-I LIAO, Tainan City (TW); TENG-CHUN HSUAN, Tainan City (TW); CHIN-CHENG CHIEN, Tainan City (TW)

(72) Inventors: CHIN-I LIAO, Tainan City (TW); TENG-CHUN HSUAN, Tainan City (TW); CHIN-CHENG CHIEN, Tainan City (TW)

(73) Assignee: United Microelectronics Corp., Hsinchu (TW)

(21) Appl. No.: 13/234,519

(22) Filed: Sep. 16, 2011

(51) Int. Cl. H01L 29/78; H01L 21/336

(52) U.S. Cl. 257/408; 438/301; 257/E29.266; 257/E21.409

(57) ABSTRACT

A semiconductor device and a method for fabricating the same are provided. The semiconductor device includes a gate structure, a source region and a drain region. The gate structure is disposed on a substrate. The source and drain regions disposed at respective sides of the gate structure include a boron-doped silicon germanium (SiGeB) layer substantially without stress relaxation. The boron-doped silicon germanium (SiGeB) layer has a germanium concentration greater than 30 at % and an in-situ doping concentration of boron ranging between 2.65×10²⁰/cm³ and 1×10²¹/cm³.

### BACKGROUND OF THE INVENTION

1. Field of the Invention

The present invention relates to a semiconductor device and a method for fabricating the same, and more particularly, to a transistor including a high Ge-content silicon germanium (SiGe) layer and a method for fabricating the same.

2. Description of Related Art

Metal oxide semiconductor (MOS) transistor is one of the most common elements used in many different semiconductor devices, such as memories, image sensors or displays. Along with rapid progress of semiconductor technology, dimensions of semiconductor devices are reduced and integrity thereof is promoted continuously to further advance the operating speed and performance of integrated circuits (ICs). However, due to the limitations in mobility of electrons and holes in silicon, applications of the transistor are confined.

Accordingly, changing the mobility of electrons and holes by means of controlling mechanical stress in the channel is proposed to further increase the operating speed. A technique for fabricating source and drain regions in the transistor is provided with using silicon germanium (SiGe) epitaxy material. As compared with characteristics of silicon, germanium has larger atomic volume and can apply a lateral compressive stress toward the channel region. Thus, the mobility of electrons and holes can be enhanced in the source and drain regions formed by SiGe, and thereby the device performance can be improved.

### SUMMARY OF THE INVENTION

Accordingly, the present invention is directed to a semiconductor device and a method for fabricating the same, wherein a doped silicon germanium layer can have an enhanced film quality and improved performance.

A semiconductor device of the present invention is provided, including a gate structure, a source region and a drain region. The gate structure is disposed on a substrate. The source and drain regions disposed at respective sides of the gate structure include a boron-doped silicon germanium (SiGeB) layer substantially without stress relaxation. The boron-doped silicon germanium (SiGeB) layer has a germanium concentration greater than 30 at % and an in-situ doping concentration of boron ranging between 2.65×10²⁰/cm³ and 1×10²¹/cm³.

According to an embodiment of the present invention, the boron-doped silicon germanium (SiGeB) layer has the in-situ doping concentration of boron ranging between 3.70×10²⁰/cm³ and 5×10²⁰/cm³. The boron-doped silicon germanium (SiGeB) layer may have the in-situ doping concentration of boron being about 3.70×10²⁰/cm³.

According to an embodiment of the present invention, the stress relaxation between the boron-doped silicon germanium (SiGeB) layer and the substrate is less than 5%.

According to an embodiment of the present invention, the source region and the drain region further include an undoped silicon germanium (SiGe) layer disposed between the boron-doped silicon germanium (SiGeB) layer and the substrate.

According to an embodiment of the present invention, the source region and the drain region further include a cap layer covering the boron-doped silicon germanium (SiGeB) layer.

According to an embodiment of the present invention, the substrate includes a pair of recesses disposed at the respective sides of the gate structure, and the boron-doped silicon germanium (SiGeB) layer fills the recesses respectively.

A method for fabricating a semiconductor device of the present invention is described as follows. A gate structure is formed on a substrate. A boron-doped silicon germanium (SiGeB) layer substantially without stress relaxation is formed at respective sides of the gate structure, wherein the boron-doped silicon germanium (SiGeB) layer has a germanium concentration greater than 30 at % and a boron concentration ranging between 2.65×10²⁰/cm³ and 1×10²¹/cm³.

According to an embodiment of the present invention, the boron-doped silicon germanium (SiGeB) layer has the boron concentration ranging between 3.70×10²⁰/cm³ and 5×10²⁰/cm³. The boron-doped silicon germanium (SiGeB) layer, for example, has the boron concentration of about 3.70×10²⁰/cm³.

According to an embodiment of the present invention, the stress relaxation between the boron-doped silicon germanium (SiGeB) layer and the substrate is less than 5%.

According to an embodiment of the present invention, the boron-doped silicon germanium (SiGeB) layer is formed by a selective epitaxy growth (SEG) process with in-situ doping of boron ions.

According to an embodiment of the present invention, the method further includes forming an undoped silicon germanium (SiGe) layer between the boron-doped silicon germanium (SiGeB) layer and the substrate. The boron-doped silicon germanium (SiGeB) layer and the undoped silicon germanium (SiGe) layer are, for example, formed in situ in a same chamber.

According to an embodiment of the present invention, the method further includes forming a cap layer to cover the boron-doped silicon germanium (SiGeB) layer. The boron-doped silicon germanium (SiGeB) layer and the cap layer are, for example, formed in situ in a same chamber.

According to an embodiment of the present invention, the method further includes forming a pair of recesses in the substrate at the respective sides of the gate structure, and the boron-doped silicon germanium (SiGeB) layer fills the recesses.

According to an embodiment of the present invention, the method further includes forming a source region and a drain region by performing an ion implantation process to the boron-doped silicon germanium (SiGeB) layer, after the boron-doped silicon germanium (SiGeB) layer is formed.

According to an embodiment of the present invention, the boron-doped silicon germanium (SiGeB) layer is formed at a temperature below about 650° C.

As mentioned above, in the semiconductor device and the method for fabricating the same in this invention, the high Ge-content silicon germanium layer is in-situ doped with the boron concentration greater than about 2.65×10²⁰/cm³. Therefore, there is substantially no need for stress relaxation between the boron-doped silicon germanium (SiGeB) layer and the substrate, and a better film quality of the boron-doped silicon germanium (SiGeB) layer can be obtained.

In order to make the aforementioned and other features and advantages of the present invention more comprehensible, preferred embodiments accompanied with figures are described in detail below.

### BRIEF DESCRIPTION OF THE DRAWINGS

The patent or application file contains at least one drawing executed in color. Copies of this patent or patent application publication with color drawings will be provided by the Office upon request and payment of the necessary fee. The accompanying drawings are included to provide a further understanding of the invention, and are incorporated in and constitute a part of this specification. The drawings illustrate embodiments of the invention and, together with the description, serve to explain the principles of the invention.

FIGS. 1A-1D depict, in a cross-sectional view, a method for fabricating a semiconductor device according to an embodiment of the present invention.

FIG. 2 schematically illustrates a measurement of the boron-doped silicon germanium (SiGeB) layer by X-ray diffraction (XRD) technique according to several examples.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

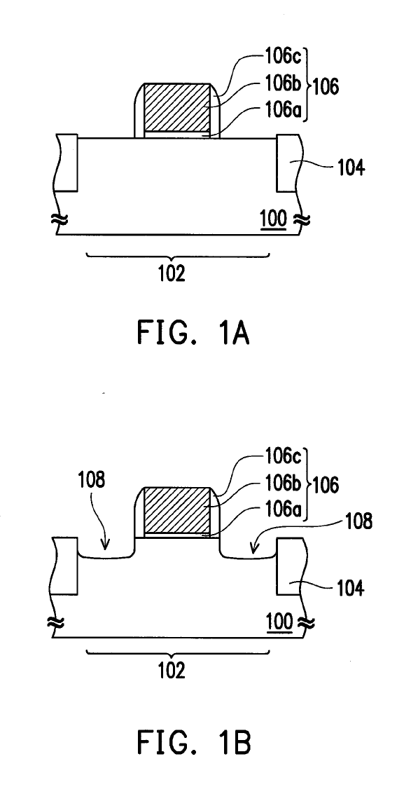

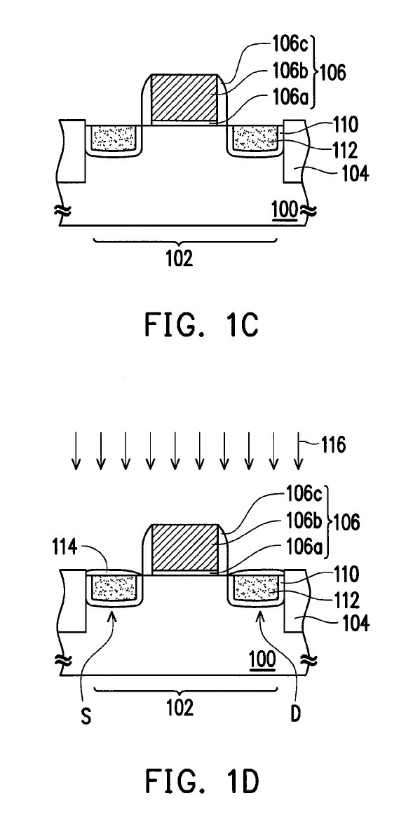

FIGS. 1A-1D depict, in a cross-sectional view, a method for fabricating a semiconductor device according to an embodiment of the present invention. Referring to FIG. 1A, a substrate 100 is provided. The substrate 100 can be a semiconductor wafer, e.g. an N- or a P-type silicon wafer. Isolation structures 104 are formed in the substrate 100, so as to define an active region 102. The isolation structures 104 are, for example, formed by shallow trench isolation (STI), and made of insulating material such as silicon oxide.

Then, a gate structure 106 is formed on the substrate 100 within the active region 102. The gate structure 106 includes a gate dielectric layer 106a, a gate 106b and a pair of spacers 106c. The gate dielectric layer 106a intervening between the gate 106b and the substrate 100 can be made of silicon oxide or silicon nitride. Alternatively, the gate dielectric layer 106a may be a composite structure of a silicon oxide layer and a high-k dielectric layer. The high-k dielectric layer is made of for example, a dielectric material with a dielectric constant greater than 4, such as hafnium oxide (HfO₂), hafnium silicon oxide (HfSiO), hafnium silicon oxynitride (HfSiON), aluminum oxide (Al₂O₃), lanthanum oxide (La₂O₃), lanthanum aluminum oxide (LaAlO), tantalum oxide (Ta₂O₅), zirconium oxide (ZrO₂), zirconium silicon oxide (ZrSiO₄), or hafnium zirconium oxide (HfZrO). The gate 106b may be made of a conductive material, such as undoped polysilicon or doped polysilicon. In another embodiment, the gate 106b can be a composite structure optionally including, in addition to the polysilicon layer, a barrier layer (e.g. TiN layer), a work function metal layer and so on. The spacers 106c are formed on respective sidewalls of the gate dielectric layer 106a and the gate 106b. For illustration purposes, each spacer 106c is described in terms of a single-layer spacer. The spacers 106c, nevertheless, can be made of a composite layer, which is not particularly limited by the present invention.

Referring to FIG. 1B, a pair of recesses 108 is then formed in the substrate 100 at the respective sides of the gate structure 106. The recesses 108 are formed by conducting an etching process using the gate structure 106 as a mask. It should be noticed that the recesses 108 each with a rectangle-like profile shown in FIG. 1B are provided for illustration purposes, and are not construed as limiting the scope of the present invention. It is appreciated by persons skilled in the art that the recesses 108 can be formed into various shapes, such as a hexagon-like profile, through multiple identical or different etching processes. Moreover, a wet cleaning process is usually performed to the recesses 108 before subsequent growth of silicon germanium therein, so as to ensure quality thereof.

Referring to FIG. 1C, after the substrate 100 is transferred to a chemical vapor deposition (CVD) reaction chamber, an optional prebaking process, e.g. thermal annealing, can be conducted before the formation of silicon germanium. The optional prebaking process may be implemented by heating the substrate 100 to a temperature of about 800° C. in H₂ ambient gas. Afterwards, an undoped silicon germanium (SiGe) layer 110 and a boron-doped silicon germanium (SiGeB) layer 112 substantially without stress relaxation are formed in the recesses 108 in sequence. The boron-doped silicon germanium (SiGeB) layer 112 fills the recesses 108, while the undoped silicon germanium (SiGe) layer 110 is formed between the boron-doped silicon germanium (SiGeB) layer 112 and the substrate 100. The undoped silicon germanium (SiGe) layer 110 and the boron-doped silicon germanium (SiGeB) layer 112 have, for example, a germanium concentration greater than 30 at %, possibly greater than 35 at %. It should be noticed that the boron-doped silicon germanium (SiGeB) layer 112 is doped with a boron concentration ranging between 2.65×10²⁰/cm³ and 1×10²¹/cm³. In an embodiment, the boron-doped silicon germanium (SiGeB) layer 112 has the boron concentration ranging between 3.70×10²⁰/cm³ and 5×10²⁰/cm³, possibly of about 3.70×10²⁰/cm³.

The undoped silicon germanium (SiGe) layer 110 may be formed by a selective epitaxy growth (SEG) process using a silicon-containing gas source, so as to form a SiGe epitaxy film. The boron-doped silicon germanium (SiGeB) layer 112 may be formed by the selective epitaxy growth (SEG) process using the silicon-containing gas source with in-situ doping of boron ions, so as to directly form a boron-doped SiGe epitaxy film. In an embodiment, the boron-doped silicon germanium (SiGeB) layer 112 and the undoped silicon germanium (SiGe) layer 110 are, for example, formed in situ in the same chemical vapor deposition (CVD) reaction chamber. In practice, the undoped silicon germanium (SiGe) layer 110 is, for example, formed at a temperature of about 700° C., and the boron-doped silicon germanium (SiGeB) layer 112 is, for example, formed at a temperature below about 650° C.

In general, interface dislocations are usually exhibited between a silicon germanium (SiGe) film with high Ge composition (e.g. >30 at %) and a silicon substrate due to lattice dismatch of these materials, and thereby a higher stress relaxation between the high Ge-content silicon germanium (SiGe) and the silicon is required for improving film quality. It is, nevertheless, proposed in this embodiment that the boron-doped silicon germanium (SiGeB) layer 112 with high Ge composition is in-situ doped with high boron concentration, which may significantly mitigate the lattice dismatch and reduce generation of the interface dislocations. Accordingly, there is substantially no need for stress relaxation between the boron-doped silicon germanium (SiGeB) layer 112 and the substrate 100. In practice, the phrase regarding “substantially without stress relaxation” described in this invention may indicate that the stress relaxation between the boron-doped silicon germanium (SiGeB) layer 112 and the substrate 100 is reduced as low as possible owing to the alleviative lattice dismatch. In an embodiment, the stress relaxation between the boron-doped silicon germanium (SiGeB) layer 112 and the substrate 100 can be less than 5%.

Referring to FIG. 1D, a cap layer 114 is optionally formed on the boron-doped silicon germanium (SiGeB) layer 112, so as to cover and protect the top surface of the boron-doped silicon germanium (SiGeB) layer 112. The cap layer 114 is, for example, made of amorphous silicon, and formation thereof can be implemented by the selective epitaxy growth (SEG) process using a silicon-containing gas source at a temperature of approximately 700° C., so as to form an amorphous silicon epitaxy film. In an embodiment, the formation of the cap layer 114 and the boron-doped silicon germanium (SiGeB) layer 112 can be also performed in situ in the same chemical vapor deposition (CVD) reaction chamber.

After the deposition of the foregoing epitaxial stack, i.e. the undoped silicon germanium (SiGe) layer 110, the boron-doped silicon germanium (SiGeB) layer 112 and the cap layer 114, an ion implantation process 116 can be performed to the boron-doped silicon germanium (SiGeB) layer 112, thereby forming a source region S and a drain region D within the recesses 108 of the substrate 100. For a PMOS transistor device, additional boron or BF₂⁺ ions are implanted into the boron-doped silicon germanium (SiGeB) layer 112 within the source region S and the drain region D, for instant. In an embodiment, the ion implantation process 116 can be conducted for implanting boron with the concentration greater than about 1×10²¹/cm³ to form the source region S and the drain region D, so as to complete the fabrication of a demanded semiconductor device. It is noted that another pair of spacers (not shown) is optionally formed on respective sides of the gate structure 106 before performing the ion implantation process 116. The formation of these source and drain regions or other components required in the semiconductor device are well appreciated by persons skilled in the art, and thus, the detailed descriptions thereof are not described herein.

It is noted that the high Ge-content silicon germanium in-situ doped with high boron concentration, i.e. the boron-doped silicon germanium (SiGeB) layer 112, can greatly alleviate the lattice dismatch between the silicon germanium and the silicon materials, and therefore, the occurrence of the interface dislocations is minimized thereby enhancing the film quality of the boron-doped silicon germanium (SiGeB) layer 112. Moreover, leakage current can be reduced in the boron-doped silicon germanium (SiGeB) layer 112 owing to the high boron doping concentration, which may lower contact resistance. Consequently, the above-mentioned fabricating procedures can advantageously obtain the high Ge-content silicon germanium film with desirable film quality and electrical properties, and eventually improve the device performance.

A semiconductor device according to an embodiment of the invention is then illustrated with FIG. 1D. It should be noted that the details of the materials, effects and forming methods of each component therein have been described explicitly in the foregoing embodiment, and will be omitted hereinafter.

Referring to FIG. 1D again, the semiconductor device includes the gate structure 106, the source region S and the drain region D. The gate structure 106 is disposed on the substrate 100, and the source region S and the drain region D are disposed at the respective sides of the gate structure 106. The source region S and the drain region D may include, in a bottom-up manner, the undoped silicon germanium (SiGe) layer 110, the boron-doped silicon germanium (SiGeB) layer 112 and the cap layer 114 disposed in the recesses 108. Since the boron-doped silicon germanium (SiGeB) layer 112 has the germanium concentration greater than 30 at % and the in-situ doping concentration of boron greater than 2.65×10²⁰/cm³, the boron-doped silicon germanium (SiGeB) layer 112 and the substrate 100 are substantially no longer in need of stress relaxation, which may imply the stress relaxation is less than 5%.

For illustration purposes, the above-mentioned disclosure is described in terms of a MOS structure as the semiconductor device, which is illustrated only as an exemplary example and thereby enables those of ordinary skill in the art to practice this invention, but should not be construed as limiting the scope of the present invention. The semiconductor device to be formed is not particularly limited by the present invention, whereas people skilled in the art should be able to embody the invention based on the illustration to obtain a high Ge-content silicon germanium (SiGe) layer with desirable properties, e.g. the boron-doped silicon germanium (SiGeB) layer 112. It is to be appreciated by those of ordinary skill in the art that other elements, such as the gate structure, the source and drain regions, and even source drain extension regions, can be arranged and fabricated based on techniques known to people skilled in the art, and are not limited to the descriptions in the following embodiments.

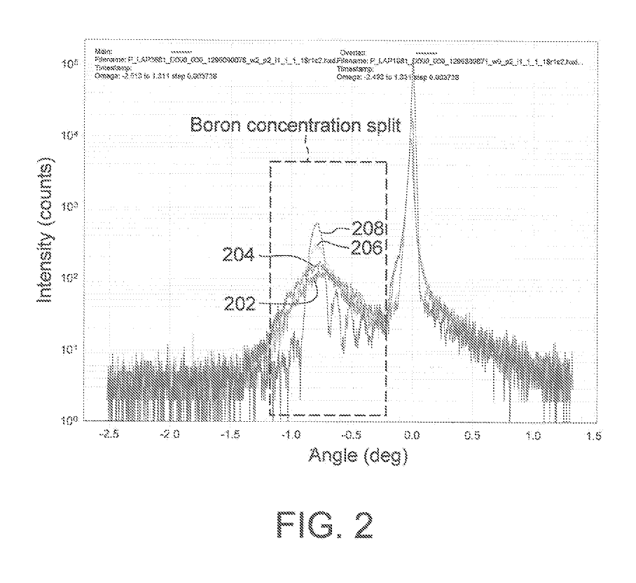

To substantiate the outstanding efficacy of the high Ge-content silicon germanium in-situ doped with high boron concentration in the present invention, actual measurements of silicon germanium films respectively doped with different boron concentrations according to several examples will be demonstrated hereinafter. It should be appreciated that the following examples are provided merely to illustrate the effects upon the stress relaxation in the present invention, but are not intended to limit the scope of the present invention. FIG. 2 schematically illustrates a measurement of the boron-doped silicon germanium (SiGeB) layer by X-ray diffraction (XRD) technique according to several examples.

In these examples, the silicon germanium films contain about 36 at % of Ge, and each is in-situ doped with respective boron concentrations of about 1.30×10²⁰/cm³, 1.70×10²⁰/cm³, 2.65×10²⁰/cm³ and 3.70×10²⁰/cm³. The resultant boron-doped silicon germanium (SiGeB) films are then analyzed by X-ray diffraction (XRD) as shown in FIG. 2, and the data is quantified in terms of stress relaxation (%) and mosaic values as depicted in Table 1.

TABLE 1

| | In-situ doping | | |
|---|---|---|---|
| Boron | concentration of boron | Stress relaxation | |
| concentration split | (cm⁻³) | (%) | Mosaic |
| peak 202 | 1.30 × 10²⁰ | 32.7 | 0.159 |
| peak 204 | 1.70 × 10²⁰ | 17.7 | 0.148 |
| peak 206 | 3.70 × 10²⁰ | 7.6 | 0.066 |
| peak 208 | 3.70 × 10²⁰ | −0.6 | 0.013 |

As shown in FIG. 2 and Table 1, it is obvious that the quantified stress relaxation and mosaic values decrease significantly as raising the boron concentration in-situ doped in the silicon germanium films, which indicates the mitigation of the lattice dismatch and the inhibition of micro-defects. Based on the above results, a better film quality of the silicon germanium film is expected with sufficiently high in-situ doping concentration of boron, so that the improvement of the device performance can be achieved.

In view of the above, the semiconductor device and the fabricating method thereof according to several embodiments described above have at least the following advantages. Since the high Ge-content silicon germanium is in-situ doped with high boron concentration, the lattice dismatch between the silicon germanium and the silicon materials can significantly mitigated, thereby minimizing the generation of the interface dislocations. In addition, the leakage current and the contact resistance can be reduced owing to the high doping concentration of boron. Accordingly, not only the film quality of the high Ge-content silicon germanium is improved, but the device performance is also enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device, comprising:
a gate structure, disposed on a substrate; and
a source region and a drain region, disposed at respective sides of the gate structure,
wherein the source region and the drain region comprise a boron-doped silicon germanium (SiGeB) layer substantially without stress relaxation, and the boron-doped silicon germanium (SiGeB) layer has a germanium concentration greater than 30 at % and an in-situ doping concentration of boron ranging between 2.65×10²⁰/cm³ and 1×10²¹/cm³.

2. The semiconductor device according to claim 1, wherein the boron-doped silicon germanium (SiGeB) layer has the in-situ doping concentration of boron ranging between 3.70×10²⁰/cm³ and 5×10²⁰/cm³.

3. The semiconductor device according to claim 1, wherein the boron-doped silicon germanium (SiGeB) layer has the in-situ doping concentration of boron being about 3.70×10²⁰/cm³.

4. The semiconductor device according to claim 1, wherein the stress relaxation between the boron-doped silicon germanium (SiGeB) layer and the substrate is less than 5%.

5. The semiconductor device according to claim 1, wherein the source region and the drain region further comprise an undoped silicon germanium (SiGe) layer, disposed between the boron-doped silicon germanium (SiGeB) layer and the substrate.

6. The semiconductor device according to claim 1, wherein the source region and the drain region further comprise a cap layer, covering the boron-doped silicon germanium (SiGeB) layer.

7. The semiconductor device according to claim 1, wherein the substrate comprises a pair of recesses disposed at the respective sides of the gate structure, and the boron-doped silicon germanium (SiGeB) layer fills the recesses respectively.

8. A method for fabricating a semiconductor device, comprising:
forming a gate structure on a substrate; and
forming a boron-doped silicon germanium (SiGeB) layer substantially without stress relaxation at respective sides of the gate structure, wherein the boron-doped silicon germanium (SiGeB) layer has a germanium concentration greater than 30 at % and a boron concentration ranging between 2.65×10²⁰/cm³ and 1×10²¹/cm³.

9. The method according to claim 8, wherein the boron-doped silicon germanium (SiGeB) layer has the boron concentration ranging between 3.70×10²⁰/cm³ and 5×10²⁰/cm³.

10. The method according to claim 8, wherein the boron-doped silicon germanium (SiGeB) layer has the boron concentration of about 3.70×10²⁰/cm³.

11. The method according to claim 8, wherein the stress relaxation between the boron-doped silicon germanium (SiGeB) layer and the substrate is less than 5%.

12. The method according to claim 8, wherein the boron-doped silicon germanium (SiGeB) layer is formed by a selective epitaxy growth (SEG) process with in-situ doping of boron ions.

13. The method according to claim 8, further comprising forming an undoped silicon germanium (SiGe) layer between the boron-doped silicon germanium (SiGeB) layer and the substrate.

14. The method according to claim 13, wherein the boron-doped silicon germanium (SiGeB) layer and the undoped silicon germanium (SiGe) layer are formed in situ in a same chamber.

15. The method according to claim 8, further comprising forming a cap layer to cover the boron-doped silicon germanium (SiGeB) layer.

16. The method according to claim 15, wherein the boron-doped silicon germanium (SiGeB) layer and the cap layer are formed in situ in the same chamber.

17. The method according to claim 8, further comprising forming a pair of recesses in the substrate at the respective sides of the gate structure, and the boron-doped silicon germanium (SiGeB) layer fills the recesses.

18. The method according to claim 8, after the boron-doped silicon germanium (SiGeB) layer is formed, further comprising forming a source region and a drain region by performing an ion implantation process to the boron-doped silicon germanium (SiGeB) layer.

19. The method according to claim 8, wherein the boron-doped silicon germanium (SiGeB) layer is formed at a temperature below about 650° C.
